(19) United States
(12) Patent Application Publication
(10) Pub. No.: US 2004/0261704 A1
(43) Pub. Date: Dec. 30, 2004

(54) Method and device for monitoring a CVD-process

(76) Inventors: Michael Heuken, Aachen (DE); Matthais Bode, Hergenrath (BE); Michael Pfeil, Wuerselen (DE); Juergen Schmitt, Aachen (DE)

Correspondence Address: ST. ONGE STEWARD JOHNSTON & REENS, LLC, 986 BEDFORD STREET, STAMFORD, CT, 06905-5619, US

(21) Appl. No.: 10/826,551

(22) Filed: Apr. 16, 2004

Related U.S. Application Data
(63) Continuation of application No. PCT/EP02/11037, filed on Oct. 2, 2002.

(30) Foreign Application Priority Data
Oct. 17, 2001 (DE) 101 51 259.7

(51) Int. Cl. C23C 16/00

(52) U.S. Cl. 118/715; 427/248.1

(57) ABSTRACT

This invention relates to a method for coating at least one substrate with one or more layers in a process chamber, in particular of a CVD installation. According to said method, starting materials, in particular in the form of organometallic reaction gases are introduced into the process chamber and their mass flow is controlled. In said chamber, the starting materials or reaction products thereof are deposited on layers on the substrate that is held by a temperature controlled substrate holder. During a coating cycle, which begins with the charging of the process chamber with the substrate or substrates and ends with the removal of the same according to a predetermined formula, the desired values of the process parameters, such as mass flows of the starting materials and temperature of the substrate holder, are set and the actual values for each substrate that correspond with the desired values of the process parameters are individually determined at intervals and are stored in a memory. During said coating cycle, or after each coating cycle, or after one or more subsequent processing steps carried out on a layer or on a layer system consisting of several layers, identifying layer characteristics, such as layer thickness and layer composition are determined and are stored by being allocated to the individualized data of the corresponding substrate. The actual values that have been obtained and the layer characteristics that have been determined for a plurality of layers deposited with the same formula are then correlated and correlation values are generated.

This application is a continuation of pending International Patent Application No. PCT/EP02/11037 filed Oct. 2, 2002 which designates the United States and claims priority of pending German Application No. 101 51 259.7 filed Oct. 17, 2001.

### FIELD OF THE INVENTION

The invention relates to a method for coating a substrate with one or more layers in a process chamber. The process chamber may in particular belong to a CVD installation. Starting materials, in particular in the form of metalorganic reaction gases, are introduced into this process chamber. The reaction gases usually originate from a liquid source through which a carrier gas, which becomes saturated with the metalorganic compound in vapor form, flows. The mass flow of the carrier gas through the source and therefore into the process chamber is regulated by means of a mass flow regulator. The mass of the reaction gas introduced into the process chamber is dependent on the vapor pressure of the liquid source. The process chamber includes a substrate holder. In the case of an MOCVD process, this substrate holder is held at a temperature by means of a heater. The temperature is regulated in accordance with a predetermined set value. One or more substrates, on which the starting materials or reaction products of the starting materials, for example pyrolytic decomposition products, are deposited, are located on the substrate holder. In other CVD processes, the substrate holder may also be cooled.

Each coating cycle takes place in accordance with a predetermined formulation which is stored in an electronic control device. The formulation includes the set values for the process parameters, such as the mass flows of the starting materials and the temperature of the substrate holder. The electronic control device is able, by switching valves in a gas supply system, to feed the reaction gases into the process chamber, to bring the substrate holder and/or process chamber to the process temperature, to adjust the total pressure in the process chamber to a set value and to control the overall process. The process, which generally starts with the loading of the process chamber with one or more substrates and ends with the removal of the substrates from the process chamber, is referred to below as the coating cycle. Each coating cycle may comprise a large number of stages in which different gas compositions are introduced into the process chamber. During the individual stages, the temperature of the substrate holder can adopt different values. In particular, it is possible for temperature ramps to be followed during a cycle stage. To produce a multiplicity of layers or layer systems of identical structure, a multiplicity of coating cycles are carried out using the same formulation. In the process, statistical or systematic deviations in the actual values of the process parameters from the set values may occur. These actual values are determined at time intervals during each coating cycle. Therefore, the masses of reaction gases which actually flow into the process chamber and/or the temperatures which are actually reached are measured and stored in a memory device. In processes in which a plurality of substrates is located on a substrate holder, the temperatures of the individual substrates are determined separately. The individual temperatures are stored on a substrate-individualized basis. After the coating cycle has ended or after one or more subsequent processing steps in which the substrate is divided up and/or components are fabricated from the coated substrates, measurements are carried out at the layer or at the layer system in order to determine characteristic layer properties, such as for example layer thickness, layer composition or electronic properties of the layers. These layer properties, which can also be determined during the coating cycle, are likewise stored on a substrate-individualized basis in the memory device.

Statistical analyses can be carried out using the actual values obtained and the layer properties determined for a multiplicity of layers deposited using the same formulation. For this purpose, the actual values obtained are brought into correlation with the layer properties determined. The correlation values which are generated are displayed or processed further by an analysis device in order to determine systematic or statistical deviations. It is preferable for all the available process parameters to be stored on a substrate-individualized basis and correlated with the properties of the layers or the components fabricated therefrom by the analysis device. This type of analysis makes it possible for certain, systematic deviations in the layer properties from statistical mean values or from set values which are to be achieved to be brought into direct correlation with certain process parameters. This makes it possible to determine the causes of deviations in the layer properties for certain substrates. For this purpose, by way of example, mean values are formed from the multiplicity of individual set values obtained for each coating cycle. These mean values are brought into correlation with the values for the layer properties. It is then investigated, for example, which of the set values has a similar profile throughout the multiplicity of coating cycles, such as a layer property. In this way, it is possible to determine the process parameter which is responsible for a deviation in a layer property for a specific substrate. Suitable process parameters are all available data, in particular data which change over the course of time, i.e. in particular the mass flows of all the process gases introduced into the process chamber, the temperatures which are measured inside the process chamber, and in particular the temperatures of the individual substrates. Furthermore, ambient parameters, such as the temperature, the humidity and the purity of the ambient air, are also suitable. The valve positions of the gas supply system are also encompassed. The surface temperature of the substrates, the rotational speed of substrates disposed rotating on a rotating substrate holder can be determined by means of measurements carried out in the process chamber during the coating operation. It is also possible to use suitable methods to determine the growth rate of the layer during the coating process in a substrate-individual manner. It is also possible for the layer properties during growth to be determined by optical inspections. All the data are stored in a substrate-specific form in the memory device.

In particular, it is possible for a very wide range of measurement variables (e.g. growth rates, temperature, reflectivity, etc.) to be recorded during layer growth in a positionally and temporally resolved form for each wafer, i.e. for each wafer the measurement variables are recorded and stored a number of times in each growth step at a series of different points on the wafer surface. One or more quality coefficients (e.g. variation in the layer thickness over the wafer) are also determined during the growth process for each wafer from these measurement variables. These quality coefficients are correlation values from the raw data determined for the measurement variables. The quality coefficients can be used to determine the further process steps for each wafer individually and automatically. By incorporating statistical data which are already available for this process, they can automatically parametrize the process parameters (temperatures, pressure, gas composition, etc.) for the subsequent, identical coating process, for the purpose of improving the quality coefficient. However, they can also be used to adapt growth steps which are still to be completed during the coating cycle, in order to ensure and improve the quality of the wafers which are already undergoing the growth process.

The measurement on the individual substrates preferably takes place at at least three different locations, so that it is also possible to determine deviations in the layer thickness and/or the deposition temperature during growth on a layer, i.e. the homogeneity thereof.

The analysis device is able to graphically present the correlation values generated. This may be effected, for example, in diagram form. For example, there is provision for the temperature profiles to be plotted in the form of a temperature/time diagram and for the temporal profile of the growth rate or another layer property to be indicated in the same diagram.

The characteristic layer properties which can be brought into correlation with the actual values obtained can be obtained in particular even during the coating cycle. It is then possible to determine the direct influence of a process parameter on a layer property and to display it in graphic form.

In particular, the quality-relevant properties of the layers are brought into correlation with the process parameters. If the layer system is to be suitable, for example, for the fabrication of quantum well lasers, the substrate temperature as a process parameter will be linked to the electronic properties or the growth rate of the layers which define the quantum well.

In the case of a PIN diode, the V-III ratio, as a characteristic layer property, will be placed in correlation with the gas temperature in the process chamber and/or with the mass flows of the V component and the III component (arsine, phosphine or TMG, TMI).

Correction values for individual process parameters can be determined from the generated correlation values by means of a correction value calculator. These correction values take account of the temporal drift of layer properties, which results, for example, from starting materials in storage tanks changing over the course of time or the conversion rate in the metalorganic sources changing as a result of consumption. The consumptions and run times of the individual components are also added up. This makes it possible to indicate that the sources need to be topped up in good time. The method according to the invention makes it possible to recognize trends and drifts in the process at an early stage and to keep the results of the process within the desired tolerance range by means of automatic compensating measures. The trends and drifts are evaluated from coating cycle to coating cycle. The automatically initiated compensating measures can compensate for the trends and drifts from coating cycle to coating cycle. This is effected by the formation of correction values, which are applied to the actual values of the formulation. The formulation does not need to be changed. The actual values stipulated by the formulation are merely corrected, and the corrected values are set by the mass flow regulators and/or the temperature regulators. This also makes it possible to cope with deposits on the process chamber walls. The influences of the deposits on the results of the process are automatically taken into account.

Correction value formation of this nature may also take place during a process cycle. By way of example, the instantaneous layer growth is determined during a process cycle. It is then possible to react to changing growth rates by shortening or lengthening a process step. In the case of an MOCVD process, there is also provision for the respective V-III ratio to be measured and for it to be possible to react to temporal deviations from the set value during a process step, for example by the V component or the III component in the gas phase being reduced or increased as a result of the associated gas flow being altered.

Exemplary embodiments of the method and of the apparatus are explained below with reference to appended drawings, in which:

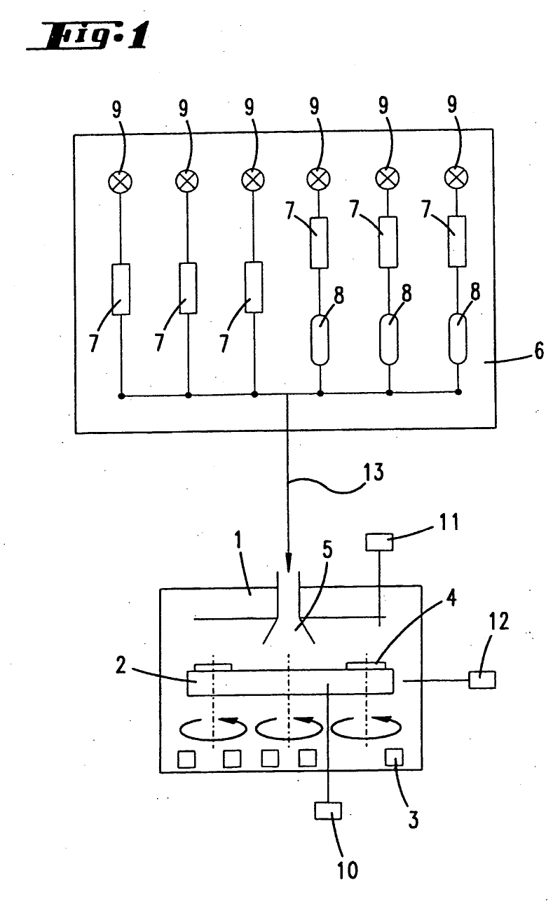

FIG. 1 shows a highly diagrammatic illustration of the process chamber of a CVD installation and the associated gas-mixing system, and

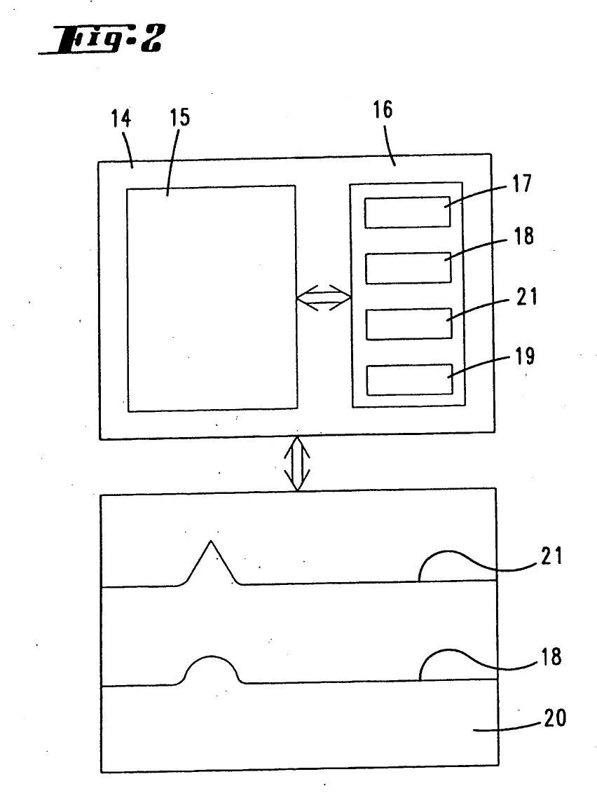

FIG. 2 shows a highly diagrammatic view of a process computer with control unit and memory unit and associated display apparatus,

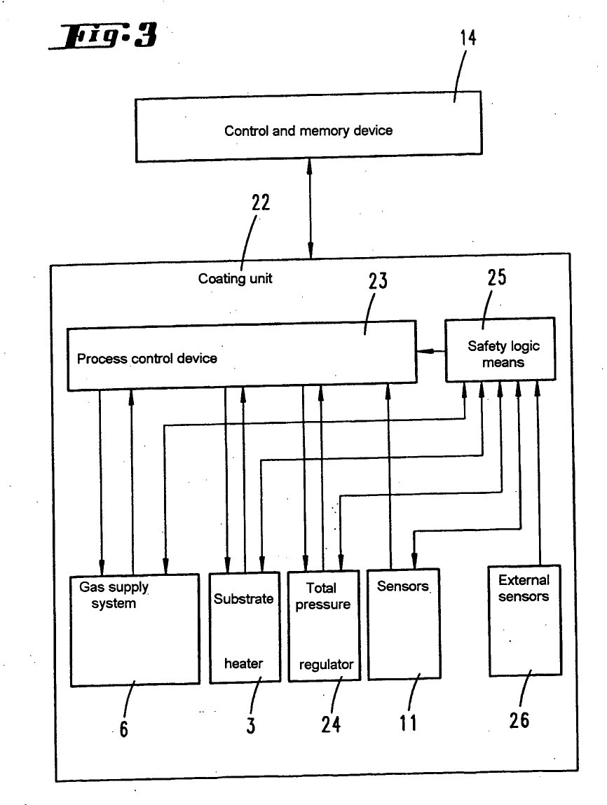

FIG. 3 shows a highly diagrammatic illustration of the hardware of a control device according to the invention,

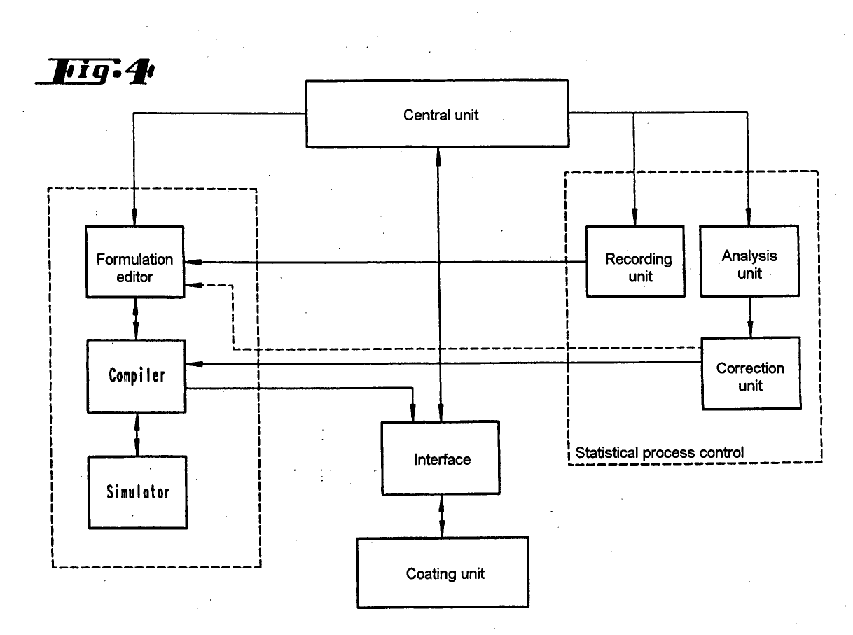

FIG. 4 shows the individual components of the associated software, and

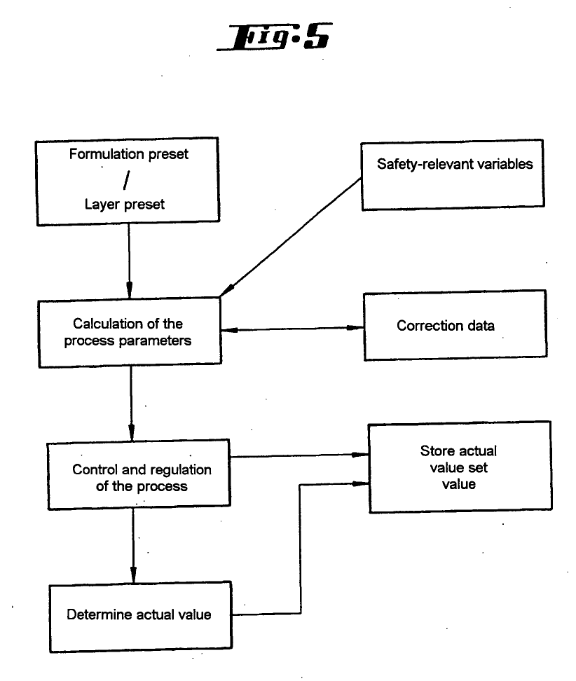

FIG. 5 shows a block diagram representing the program sequence.

In a process chamber 1 there is a substrate holder 2 which is in the form of a circular disk and is driven in rotation about its axis. A multiplicity of substrates 4 is disposed around the center of the substrate holder 2 in planetary manner on the top side of the substrate holder 2. These substrates 4 are likewise driven in rotation. For this purpose, they can be disposed on corresponding rotating sections of the substrate holder 2. Beneath the substrate holder 2 there is a heater 3, for example in the form of a high-frequency source. The temperature of the substrate holder 2 is measured by means of a thermocouple 10. The rotation of the substrate holder 2 and/or the rotation of the substrates 4 is measured using a rotational speed measuring device 12. The temperature of the substrate surface can be measured by means of an optical temperature-measuring apparatus 11. By correlating the values supplied by the temperature-measuring sensor 11 and the data supplied by an additional rotary encoder, which is illustrated, it is possible for the temperature measured by the temperature-measuring sensor 11 to be associated with each individual substrate 4 individually. These measured values are determined at preset time intervals and are stored in an actual/set value memory 18 of a memory device 16 of the process computer 14.

The process gases are provided by a gas-mixing system 6. FIG. 1 provides a highly diagrammatic illustration of the structure of a gas-mixing system 6 of this type. The individual reaction gases, such as for example arsine, phosphine or the like, and also carrier gases, such as noble gases or hydrogen or nitrogen, are switched by means of valves 9. The gases which are introduced into the gas inlet 5 of the process chamber 1 through the feed line 13 are regulated by means of mass flow regulators 7. The metalorganic components originate from vaporization sources 8 through which a carrier gas, which is likewise switched by valves 9 and the flow of which is regulated by means of mass flow regulators 7, is passed. The control device 15 provides set values to the mass flow regulators 7. The mass flow regulators 7, like the sensors 10 to 12 described above, feed back actual values. The set values and the actual values are stored on a substrate-specific basis in the actual/set value memory 18.

The process is controlled by the control device 15 in accordance with a formulation which is stored in a formulation memory 17, where the process parameters are stored in the form of set values which are adjusted at certain times.

During the coating process, characteristic layer properties 21 are determined at the deposited layer, for example using optical or other forms of sensors not shown in the drawing. These characteristic layer properties 21 are then stored in a corresponding memory 21. However, there is also provision for the characteristic layer properties, such as layer thickness, V-III ratio or electronic properties of the layer, to be measured at a later stage. These data are also stored in the memory 21 in substrate-based form.

Correlation values 19 are then formed using these data, i.e. using the actual/set values 18 for the process parameters and the layer properties 21. This is implemented, for example, by the historic profile of the actual values 18 being compared with the historic profile of the layer properties 21. The individual curves or functions formed in this way are compared with one another in order to discover characteristic deviations and/or correspondences.

By way of example, a layer property of a substrate which has been coated with a layer in a very specific coating cycle may have a certain deviation from the mean value. This can be presented graphically, as illustrated in the figures. In this case, the actual value profiles can be analyzed to determine whether the corresponding coating cycle has a deviation from the mean value. This makes it possible to determine the cause of a quality deviation.

The process computer 14 is also able to simulate a coating cycle. This is carried out by means of virtual actuators, such as valves, mass flow regulators or heaters. The actuators are set in accordance with the formulation and feed back virtual actual values. A plausibility check is carried out in accordance with predetermined rules which are stored in the process computer. These rules state, for example, that a certain valve must not be opened before another valve or that a valve may only open when a certain total pressure or a certain temperature is prevailing in the process chamber.

Other safety-relevant data relating to the environment of the CVD installation can also be incorporated in the plausibility check. By way of example, the ambient air can be checked for the presence of reaction gases. If a reaction gas is present in the ambient air, this indicates a leak in the CVD installation or a defective gas discharge.

With the method according to the invention and the apparatus according to the invention, it is possible to determine quality defects or to make predictions as to how certain layer properties change in the event of a change in one or more process parameters, by means of retrospective analysis on the basis of characteristic layer properties determined at the substrate either after the coating cycle or during the coating cycle and process parameters stored during the coating cycle.

The method according to the invention is able to react to short-term and long-term deviations in the actual parameters from the set parameters. However, the method is also able to detect trends or drifts in the layer properties both during a coating cycle and over the history of a multiplicity of coating cycles. It is able to use the deviations in the actual values for the layer properties from the set values and the correlation values obtained to determine correction values which can be used to vary the process parameters in order to compensate for the detected trends and drifts in the process at an early stage. In this context, it is not the formulation which is influenced, but rather the set values which are fed to the mass flow regulators or temperature regulators.

In this context, the possibility of, within the formulation, stipulating not the times of individual process steps, but rather their result on a layer property, such as for example the layer thickness, is of independent importance. In accordance with the formulation, a layer with a defined composition and a defined layer thickness should be deposited within a defined process step. During the process, the layer growth is observed in situ by means of optical sensors. The growth rate or the instantaneous layer thickness is measured. When the layer thickness reaches its set value, the coating step is terminated and the next coating step is then embarked upon. This method also makes it possible to prevent trends and drifts.

FIGS. 3 to 5 show a highly diagrammatic illustration of the software components and hardware components of the apparatus according to the invention.

FIG. 3 shows a control and memory device 14 in which the editing of the formulation, the plausibility check of the formulation and the translation of the formulation into process control signals in a compiler. These process control signals are fed via a data line to the coating unit 22. This coating unit may be spatially separate from the control and memory device 14. The coating unit 22 may be an MOCVD installation, an apparatus for depositing oxides or an apparatus for depositing organic substances. The control and memory device 14 can also interact with a plurality of, in particular different,. coating units 22. By way of example, there is provision for the control and memory device 14 to interact with a plurality of coating units 22 which are connected to a common transfer chamber.

The process control signals are processed further in the coating unit 22 by a process control device 23. These signals are used to actuate the individual mass flow regulators of the gas supply system 6 and/or the heater 3. A total pressure regulator 24 is likewise provided with control data from the process control device 23. The mass flow regulators of the gas supply system 6 and/or the heater of the substrate 3 and the total pressure regulator 24 feed back actual values to the process control device 23. These actual values are passed to the control and memory device 14 via the data line.

Furthermore, the coating unit 22 has a safety logic means 25. The safety logic means processes a large quantity of input data. The input data may be the valve positions, the mass flows, the temperatures, i.e. any desired process parameters. However, data which are determined by sensors 11 of the coating unit, i.e. for example pressures, external temperatures or the like, also constitute input data for the safety logic means. The safety logic means is also fed data determined by external sensors 26, for example data about whether the feed air system or waste air system is functioning appropriately. The safety logic means is able to automatically transfer the coating unit into a safe operating state if the sensors 11, 26 detect errors. The corresponding logic means is hardwired and therefore protected from programming errors.

The control and memory device illustrated in FIG. 4 has a module which includes a formulation editor. This module can be used to preselect the layer sequence which is to be deposited. This is implemented by means of, for example, by means of a menu, from which a combination can be selected from a large number of standard formulations in order for the desired layer sequence to be deposited. However, it is also possible for the layer sequence to be edited by means of a special syntax in the formulation editor. There is also provision for the individual mass flow regulators and/or valves to be acted on directly by the formulation editor. Furthermore, the control and memory device 14 also has a module which allows statistical process control. This module is able in particular to evaluate the set values transferred from the coating unit via an interface. The data supplied at the interface are distributed by means of a central unit. The analysis unit which is assigned to the statistical process control is furthermore able to determine the abovementioned correction values. This takes place in a correction unit connected downstream of the analysis unit. All the actual and set values are stored in a recording unit. The values determined by the correction unit are fed to the module of the formulation editor. The correction values are either fed direct to the compiler or into the formulation editor, where they can be taken into account during the editing of the process steps.

FIG. 5 shows a highly diagrammatic illustration of the sequence of a coating cycle. After the formulation has been preset and/or the layer system to be deposited has been selected, the compiler, using the simulator, calculates the process parameters. In doing so, it is if appropriate also possible to use correction data. Safety-relevant variables are also taken into account in the calculation of the process parameters.

Actual values are determined during the control and regulation of the process and are stored together with the associated set values.

In the event of certain layer properties drifting away from the set values, compensating measures can be taken immediately by means of the statistical process control of the main process parameters.

All features disclosed are (inherently) pertinent to the invention. The content of disclosure of the associated/appended priority documents (copy of the prior application) is hereby incorporated in its entirety into the disclosure of the application, partly with a view to incorporating features of these documents in claims of the present application.

What is claimed is:

1. Method for coating at least one substrate (4) with one or more layers in a process chamber (1) in particular of a CVD installation, in which starting materials, in particular in the form of metalorganic reaction gases, are introduced with mass flow control into the process chamber (1), where the starting materials or reaction products thereof are deposited on the substrate (4), which is supported by a temperature-controlled substrate holder (2), in such a manner as to form layers, where the set values for the process parameters (18), such as mass flows of the starting materials and temperature of the substrate holder, are adjusted during a coating cycle, which starts with the loading of the process chamber (1) with the one or more substrates and ends with the removal thereof, in accordance with a predetermined formulation, the actual values for each substrate associated with the set values for the process parameters being determined in an individualized manner at intervals during the coating cycle and stored in a memory, characteristic layer properties (21), such as layer thickness, layer composition, being determined at the layer or at a layer system comprising a plurality of layers during the coating cycle or after each coating cycle or after one or more subsequent processing steps, and being stored such that they are associated with the individualized data for the associated substrate, the actual values obtained and the layer properties determined for a multiplicity of layers deposited using the same formulation being brought into correlation and correlation values being generated.

2. Apparatus for coating at least one substrate with one or more layers in a process chamber in particular of a CVD installation, having feed lines (13) for starting materials, in particular in the form of metalorganic reaction gases, which are introduced with mass flow control (7) into the process chamber (1), where the starting materials or reaction products thereof are deposited on the substrate (4), which is supported by a temperature-controlled substrate holder (2), in such a manner as to form layers, and having a control and memory device (14), the set values for the process parameters, such as mass flows of the starting materials and temperature of the substrate holder, being adjusted in a coating cycle, which starts with the loading of the process chamber (1) with the one or more substrates and ends with the removal thereof, by the control device (15) in accordance with a predetermined formulation which is stored in the memory device (16) and comprises said set values for the process parameters, the actual values for each substrate associated with the set values for the process parameters (18) being determined in an individualized manner at intervals during the coating cycle and being stored in a memory of the memory device, it being possible for characteristic layer properties (21), such as layer thickness, layer composition, which can be determined at the layer or at a layer system comprising a plurality of layers, to be stored, in a form which is associated on an individualized basis with the associated substrate, in a layer property memory of the memory device during or after each coating cycle or after one or more subsequent processing steps, having an analysis device for linking the actual values obtained and the layer properties (21) determined for a multiplicity of layers deposited using the same formulation, in order to generate correlation values, and having a display device for displaying the correlation values (19).

3. Method according to claim 1 or in particular according thereto or apparatus according to claim 2 or in particular according thereto, characterized in that to generate the correlation values (19) systematic or statistical deviations of the set values from a mean set value or the associated actual values are formed.

4. Method or apparatus according to one or more of the preceding claims or in particular according thereto, characterized in that to generate the correlation values (19) mean values are formed from the actual values (18) of each coating cycle, and deviations from the mean values are generated.

5. Method or apparatus according to one or more of the preceding claims or in particular according thereto, characterized in that correction values which are applied to the actual values of the formulation are determined from the correlation values.

6. Method or apparatus according to one or more of the preceding claims or in particular according thereto, characterized in that the formulation includes stipulations concerning certain layer properties, for example the layer thickness, and during a process step this layer property is measured in situ, and the step is ended when a set value provided in the formulation for this layer property is reached.

7. Method or apparatus according to one or more of the preceding claims or in particular according thereto, characterized in that the correlation values generated are graphic representations (20) of the temporal profiles of the actual values (18), which are placed in a relationship with the characteristic layer properties (21).

8. Method or apparatus according to one or more of the preceding claims or in particular according thereto, characterized in that the set values for the process parameters are provided by an electronic control device to decentralized regulators, such as mass flow regulators (7) or temperature regulators (10), and the actual values are fed back by actual value pick-ups, associated with the regulators, to the electronic control device (15).

9. Method or apparatus according to one or more of the preceding claims or in particular according thereto, characterized in that the process parameters are also the valve positions of the valves (9) of a gas supply system (6), the temperature of liquid metalorganic sources (8), the rotational speed and the temperature of a substrate holder (2) which carries a plurality of substrates (4) and substrate temperatures which can be associated with each substrate individually.

10. Method or apparatus according to one or more of the preceding claims or in particular according thereto, characterized in that, in addition to the actual values for the process parameters, process properties which are determined at intervals during the coating cycle, such as substrate temperature, rotational speed of the substrate, growth rate of the layer and/or surface properties of the layer, are stored and brought into correlation with the layer properties.

11. Method or apparatus according to one or more of the preceding claims or in particular according thereto, characterized in that the sequence of the set values stored in the formulation (17) is subjected to a plausibility check prior to a coating cycle.

12. Method or apparatus according to one or more of the preceding claims or in particular according thereto, characterized in that the plausibility check is carried out as a coating cycle which is simulated in the control device and during which the set values are provided to virtual regulating and actuating elements which feed back virtually generated actual values.

13. Method or apparatus according to one or more of the preceding claims or in particular according thereto, characterized in that environment-related properties, such as ambient air humidity, ambient air temperature and ambient air purity, are stored at intervals on an individualized basis for each substrate and are brought into correlation with the layer properties.
